(19) United States
(12) Patent Application Publication
(10) Pub. No.: US 2013/0056857 A1
(43) Pub. Date: Mar. 7, 2013

(54) DEVICE CHIP AND MANUFACTURING METHOD THEREFOR

(71) Applicant: Koichi KONDO, Ota-Ku (JP)

(72) Inventor: Koichi KONDO, Ota-Ku (JP)

(73) Assignee: DISCO CORPORATION, Tokyo (JP)

(21) Appl. No.: 13/605,257

(22) Filed: Sep. 6, 2012

(30) Foreign Application Priority Data
Sep. 6, 2011 (JP) 2011-193600

(51) Int. Cl. H01L 23/544; H01L 21/78

(52) U.S. Cl. 257/618; 438/460; 257/E23.179; 257/E21.599

(57) ABSTRACT

A manufacturing method for a device chip having a substrate, a device formed on the front side of the substrate, and chip identification information marked inside the substrate includes preparing a device wafer having a base wafer and a plurality of devices formed on the front side of the base wafer so as to be partitioned by division lines, next applying a laser beam having a transmission wavelength to the device wafer from the back side thereof in the condition where the focal point of the laser beam is set inside the base wafer at the positions respectively corresponding to the devices, thereby forming a plurality of modified layer marks as the chip identification information inside the base wafer at the positions respectively corresponding to the devices, and finally dividing the device wafer along the division lines to obtain a plurality of device chips.

### BACKGROUND OF THE INVENTION

1. Field of the Invention

The present invention relates to a device chip having chip identification information marked therein and a manufacturing method for the device chip.

2. Description of the Related Art

A plurality of device chips such as ICs and LSIs are obtained by using a cutting apparatus or a laser processing apparatus to cut a semiconductor wafer. Usually, chip identification information such as device function, product number, and lot number is marked on the back side of each device chip. An assembly step subsequent to this marking step and the shipment of each device are managed according to this chip identification information. Japanese Patent Laid-open No. 2008-178886 discloses a method of forming chip identification information by laser marking on the back side of each device chip in the condition of a wafer prior to cutting the wafer into the individual device chips.

### SUMMARY OF THE INVENTION

In the chip identification information marking method disclosed in Japanese Patent Laid-open No. 2008-178886 mentioned above, the chip identification information is marked on the back side of each device chip. Accordingly, in the case that the back side of each device chip has a scratch, it is difficult to read the chip identification information.

It is therefore an object of the present invention to provide a device chip which can facilitate reading of the chip identification information even when the outside surface of each device chip has a scratch.

It is another object of the present invention to provide a manufacturing method for such a device chip.

In accordance with an aspect of the present invention, there is provided a device chip including a substrate, and a device formed on the front side of the substrate, wherein chip identification information is marked inside the substrate.

In accordance with another aspect of the present invention, there is provided a manufacturing method for a device chip having chip identification information marked inside a substrate, the manufacturing method including: a device wafer preparing step of preparing a device wafer including a base wafer, and a plurality of devices respectively formed in a plurality of regions partitioned by a plurality of crossing division lines on the front side of the base wafer; a chip identification information marking step of applying a laser beam having a transmission wavelength to the device wafer prepared by the device wafer preparing step, to the device wafer from the back side of the device wafer in the condition where the focal point of the laser beam is set inside the base wafer at the positions respectively corresponding to the devices, thereby forming a plurality of modified layer marks as the chip identification information inside the base wafer at the positions respectively corresponding to the devices; and a dividing step of dividing the device wafer along the division lines to obtain a plurality of device chips after performing the chip identification information marking step.

According to the present invention, the modified layer mark as the chip identification information is formed inside each device chip. Accordingly, even when the outside surface of each device chip has a scratch, the chip identification information of each device chip can be read.

The above and other objects, features and advantages of the present invention and the manner of realizing them will become more apparent, and the invention itself will best be understood from a study of the following description and appended claims with reference to the attached drawings showing some preferred embodiments of the invention.

### BRIEF DESCRIPTION OF THE DRAWINGS

FIG. 1 is a perspective view of a device wafer as viewed from the front side thereof;

FIG. 2 is a schematic perspective view of a laser processing apparatus for performing the device chip manufacturing method according to the present invention;

FIG. 3 is a block diagram showing the configuration of a laser beam generating unit;

FIG. 4 is a perspective view showing a chip identification information marking step;

FIG. 5 is a sectional view of the device wafer obtained by performing the chip identification information marking step;

FIG. 6 is a perspective view showing a back grinding step of the device wafer; and

FIG. 7 is a perspective view of a device chip having chip identification information marked therein.

### DETAILED DESCRIPTION OF THE PREFERRED EMBODIMENT

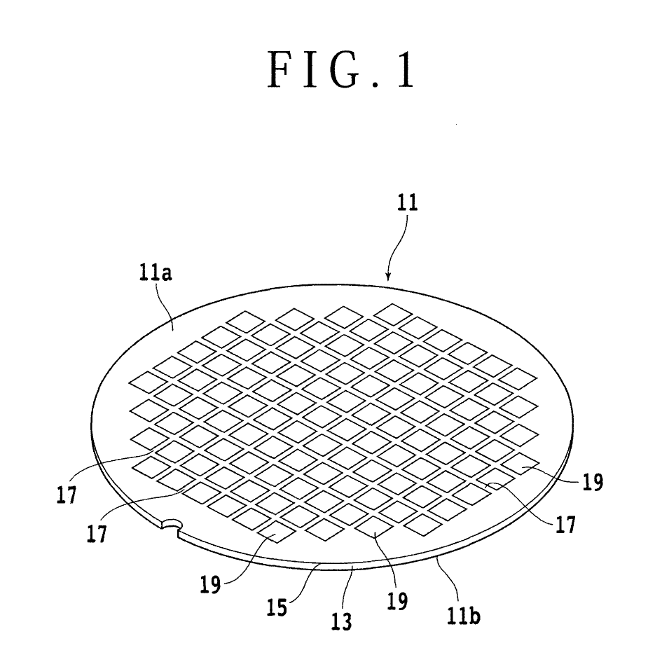

A preferred embodiment of the present invention will now be described in detail with reference to the drawings. FIG. 1 is a perspective view of a device wafer 11. As shown in FIG. 1, the device wafer 11 is composed of a base wafer 13 and a semiconductor layer 15 formed on the base wafer 13. The device wafer 11 has a front side 11a on which the semiconductor layer 15 is formed and a back side 11b to which the base wafer 13 is exposed. The base wafer 13 has a thickness of 700 μm, for example, and the semiconductor layer 15 has a thickness of 5 μm, for example. The semiconductor layer 15 is formed with a plurality of devices 19 such as ICs and LSIs, which are partitioned by a plurality of crossing division lines (streets) 17.

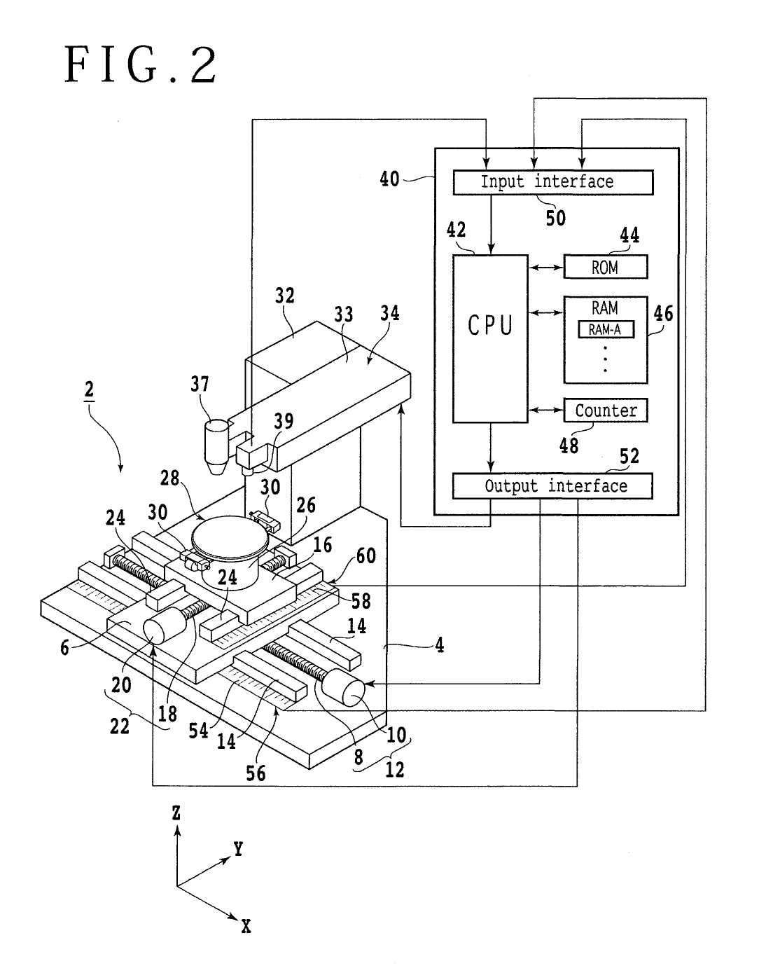

FIG. 2 is a schematic perspective view of a laser processing apparatus 2 for performing the device chip manufacturing method according to the present invention. The laser processing apparatus 2 includes a stationary base 4 and a first slide block 6 supported to the stationary base 4 so as to be movable in the X direction shown by an arrow X. The first slide block 6 is movable in a feeding direction, i.e., in the X direction along a pair of guide rails 14 by feeding means 12 including a ball screw 8 and a pulse motor 10.

A second slide block 16 is supported to the first slide block 6 so as to be movable in the Y direction shown by an arrow Y. The second slide block 16 is movable in an indexing direction, i.e., in the Y direction along a pair of guide rails 24 by indexing means 22 including a ball screw 18 and a pulse motor 20. A chuck table 28 is supported through a cylindrical support member 26 to the second slide block 16. Accordingly, the chuck table 28 is movable both in the X direction and in the Y direction by the feeding means 12 and the indexing means 22.

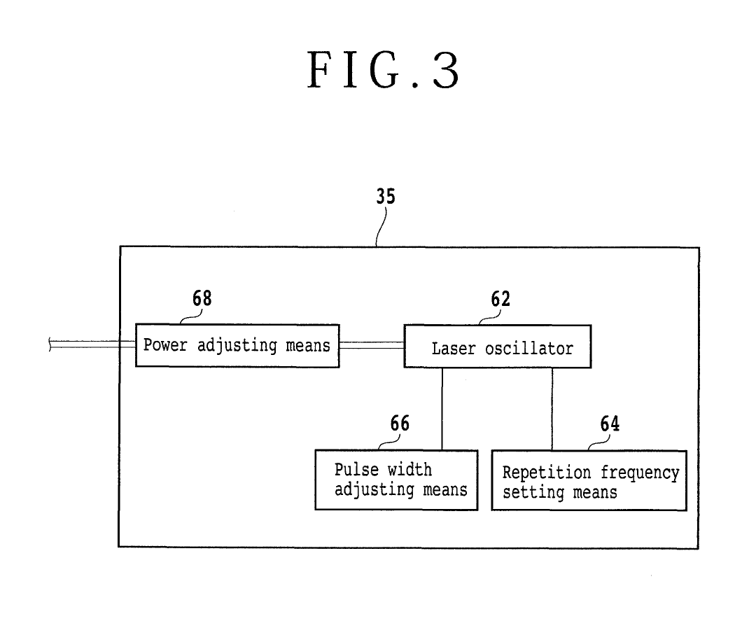

The chuck table 28 is provided with a pair of clamps 30 for clamping a semiconductor wafer held on the chuck table 28 under suction. In the device chip manufacturing method according to this preferred embodiment, the clamps 30 are not used. A column 32 is provided on the stationary base 4, and a laser beam applying unit 34 is mounted on the column 32. The laser beam applying unit 34 includes a casing 33, a laser beam generating unit 35 (see FIG. 3) accommodated in the casing 33, and a focusing unit 37 mounted on the front end of the casing 33.

As shown in FIG. 3, the laser beam generating unit 35 includes a laser oscillator 62 such as a YAG laser oscillator or a YVO4 laser oscillator, repetition frequency setting means 64, pulse width adjusting means 66, and power adjusting means 68. Although not especially shown, the laser oscillator 62 has a Brewster window and oscillates a laser beam of linearly polarized light. Referring back to FIG. 1, an imaging unit 39 for detecting a processing area of the semiconductor wafer to be laser-processed is also provided at the front end of the casing 33 so as to be juxtaposed to the focusing unit 37 in the X direction. The imaging unit 39 includes an ordinary imaging device such as a CCD for imaging the processing area of the semiconductor wafer by using visible light.

The imaging unit 39 further includes infrared imaging means composed of infrared light applying means for applying infrared light to the semiconductor wafer, an optical system for capturing the infrared light applied to the semiconductor wafer by the infrared light applying means, and an infrared imaging device such as an infrared CCD for outputting an electrical signal corresponding to the infrared light captured by the optical system. An image signal output from the imaging unit 39 is transmitted to a controller (control means) 40.

The controller 40 is configured by a computer, and it includes a central processing unit (CPU) 42 for performing operational processing according to a control program, a read only memory (ROM) 44 for preliminarily storing the control program, a random access memory (RAM) 46 as a readable/writable memory for storing the results of computation, etc., a counter 48, an input interface 50, and an output interface 52.

Reference numeral 56 denotes feed amount detecting means including a linear scale 54 provided along one of the guide rails 14 and a read head (not shown) provided on the first slide block 6. A detection signal from the feed amount detecting means 56 is input into the input interface 50 of the controller 40. Reference numeral 60 denotes index amount detecting means including a linear scale 58 provided along one of the guide rails 24 and a read head (not shown) provided on the second slide block 16. A detection signal from the index amount detecting means 60 is input into the input interface 50 of the controller 40. An image signal from the imaging unit 39 is also input into the input interface 50 of the controller 40. On the other hand, control signals are output from the output interface 52 of the controller 40 to the pulse motor 10, the pulse motor 20, and the laser beam applying unit 34.

In the device chip manufacturing method according to the present invention, a chip identification information marking step is performed in such a manner that a laser beam having a transmission wavelength to the device wafer 11 is applied to the device wafer 11 from the back side 11b thereof in the condition where the focal point of the laser beam is set inside the base wafer 13 at the positions respectively corresponding to the devices 19, thereby forming a plurality of modified layer marks as chip identification information inside the base wafer 13 at the positions respectively corresponding to the devices 19.

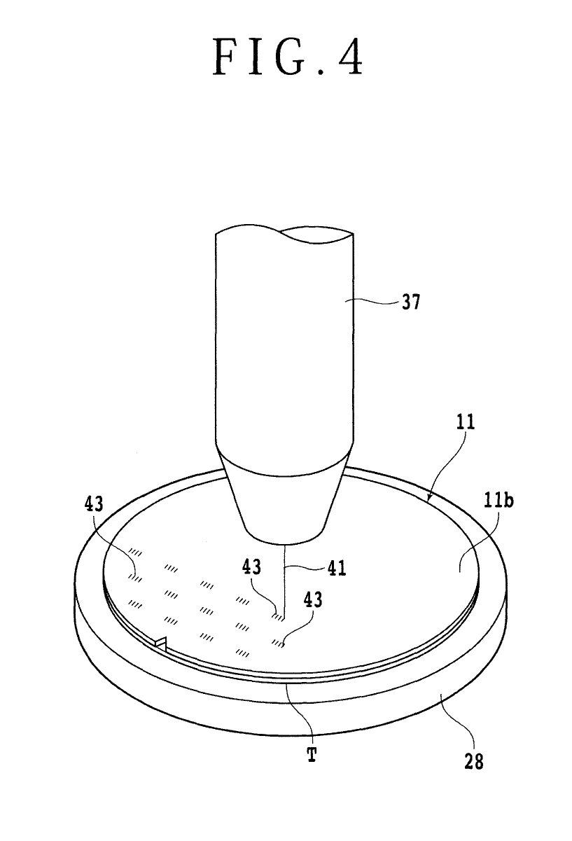

In performing this chip identification information marking step, a protective tape T is attached to the front side 11a of the device wafer 11 as shown in FIG. 4, and the device wafer 11 is held through the protective tape T on the chuck table 28 of the laser processing apparatus 2 under suction. Thereafter, the chuck table 28 is moved in the X direction and the Y direction to position the device wafer 11 directly below the imaging unit 39. In this condition, the device wafer 11 is imaged from the back side 11b by the infrared imaging means included in the imaging unit 39, thereby detecting the positions of the devices 19 and storing them into the RAM 46 of the controller 40.

In performing laser marking, a predetermined one of the devices 19 to be laser-marked is positioned directly below the focusing unit 37 according to the positional information stored in the RAM 46. Thereafter, a laser beam 41 having a transmission wavelength to the device wafer 11 is applied to the device wafer 11 from the back side 11b thereof in the condition where the focal point of the laser beam 41 is set inside the base wafer 13 at the position corresponding to the predetermined device 19. At the same time, the chuck table 28 is moved in the X direction and the Y direction to form a modified layer mark 43 as chip identification information including characters and marks inside the base wafer 13 at the position corresponding to the predetermined device 19.

After forming the modified layer mark 43 inside the base wafer 13 at the position corresponding to the predetermined device 19 as mentioned above, the chuck table 28 is sequentially moved in the X direction with the pitch of the division lines 17 to similarly form a plurality of modified layer marks 43 inside the base wafer 13 at the positions respectively corresponding to the devices 19 in one row. After forming the modified layer marks 43 inside the base wafer 13 at the positions respectively corresponding to the devices 19 in one row as mentioned above, the chuck table 28 is moved in the Y direction by the pitch of the division lines 17 to similarly perform laser marking for the devices 19 in the next row.

Such laser marking is sequentially performed for the devices 19 in the other rows to form a plurality of modified layer marks 43 inside the base wafer 13 at the positions respectively corresponding to all the other devices 19. Each modified layer mark 43 is formed as a melted and rehardened region, which means a region different from its ambient region in density, refractive index, mechanical strength, or any other physical properties in the base wafer 13 due to the application of the laser beam.

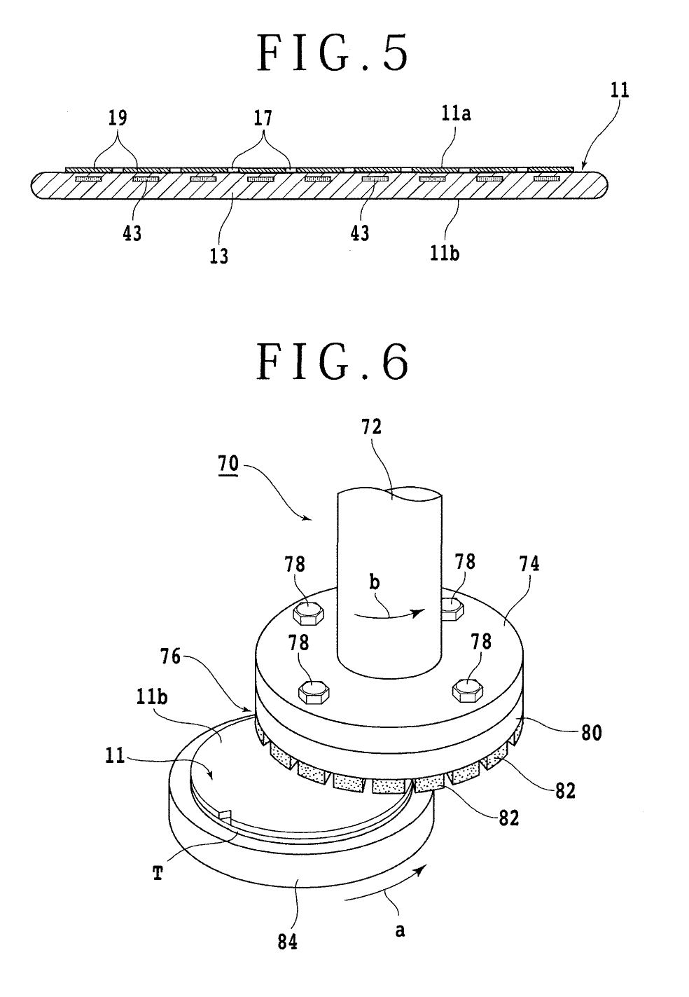

FIG. 5 is a sectional view of the device wafer 11 obtained by performing the chip identification information marking step mentioned above. As apparent from FIG. 5, the modified layer marks 43 as the chip identification information are preferably formed inside the base wafer 13 near the front side thereof at the positions respectively corresponding to the devices 19. The reason for locating the modified layer marks 43 near the front side of the base wafer 13 is that the back side 11b of the device wafer 11 is ground in the next step (back grinding step) to reduce the thickness of the device wafer 11 to a predetermined thickness (e.g., 100 μm).

The chip identification information marking step mentioned above is performed under the following processing conditions, for example.

Light source: LD pumped Q-switched Nd:YVO4 pulsed laser

Wavelength: 1064 nm

Power: 0.1 W

Repetition frequency: 50 kHz

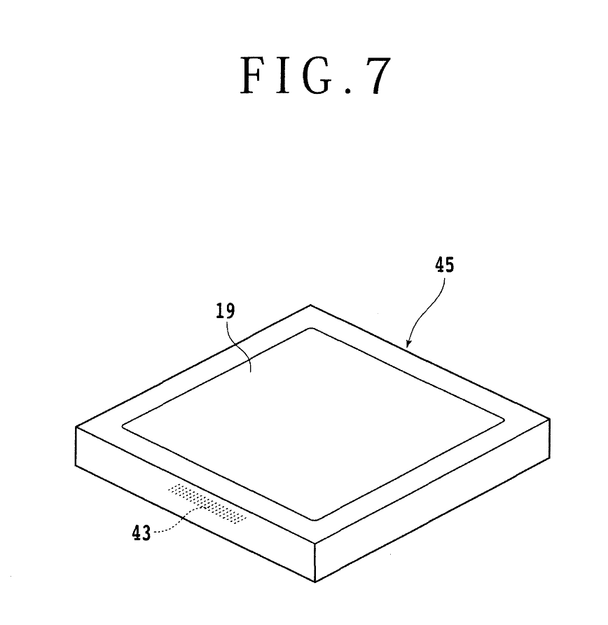

After performing the chip identification information marking step mentioned above, a back grinding step is performed in such a manner that the back side 11b of the device wafer 11 is ground to reduce the thickness of the device wafer 11 to a predetermined thickness. This back grinding step will now be described with reference to FIG. 6. Referring to FIG. 6, there is shown an essential part of a grinding apparatus for performing the back grinding step, wherein the grinding apparatus includes a grinding unit 70 and a chuck table 84. The grinding unit 70 includes a spindle 72, a wheel mount 74 fixed to the lower end of the spindle 72, and a grinding wheel 76 detachably mounted on the lower surface of the wheel mount 74 by screws 78. The grinding wheel 76 is composed of an annular base 80 and a plurality of abrasive members 82 fixed to the periphery of the lower surface of the annular base 80.

In this back grinding step, the device wafer 11 is held on the chuck table 84 in the condition where the back side 11b of the device wafer 11 is oriented upward as shown in FIG. 6. Thereafter, the chuck table 84 is rotated at 300 rpm, for example, in the direction shown by an arrow a in FIG. 6, and the grinding wheel 76 is rotated at 6000 rpm, for example, in the direction shown by an arrow b in FIG. 6. In such a rotating condition, the grinding wheel 76 is lowered to bring the abrasive members 82 into contact with the back side 11b of the device wafer 11 and then fed downward by a predetermined amount to grind the back side 11b of the device wafer 11. In grinding the back side 11b of the device wafer 11, the thickness of the device wafer 11 is measured by using a contact type or noncontact type thickness measurement gauge until the predetermined thickness (e.g., 100 μm) of the device wafer 11 is reached.

While the back grinding step is performed after the chip identification information marking step in this preferred embodiment, these steps may be reversed in order. That is, after performing the back grinding step to reduce the thickness of the device wafer 11 to a predetermined thickness, the chip identification information marking step by laser marking may be performed. After performing the chip identification information marking step and the back grinding step as mentioned above, a dividing step is performed in such a manner that the device wafer 11 is divided along the division lines 17 to obtain a plurality of device chips.

This dividing step may be performed by using the laser processing apparatus 2 shown in FIG. 2. As a first method using the laser processing apparatus 2, a laser beam having a transmission wavelength (e.g., 1064 nm) to the device wafer 11 is applied to the device wafer 11 from the back side 11b thereof in the condition where the focal point of the laser beam is set inside the device wafer 11 at the positions respectively corresponding to the division lines 17, thereby forming a plurality of modified layers as break start points inside the device wafer 11 along the division lines 17.

As a second method using the laser processing apparatus 2, a laser beam having an absorption wavelength (e.g., 355 nm) to the device wafer 11 is applied to the device wafer 11 from the back side 11b thereof in the condition where the focal point of the laser beam is set on the back side 11b of the device wafer 11 at the positions respectively corresponding to the division lines 17, thereby forming a plurality of laser processed grooves as break start points along the division lines 17 by ablation.

After performing the modified layers or the laser processed grooves as the break start points along all of the division lines 17 as mentioned above, an expand tape is attached to the back side 11b of the device wafer 11 and this expand tape is next expanded to apply an external force to the device wafer 11, thereby dividing the device wafer 11 along the division lines 17 to obtain a plurality of device chips 45 (see FIG. 7).

The dividing step may be performed by using a dicing apparatus well known in the art rather than the laser processing apparatus 2. In this case, the device wafer 11 is divided by dicing along the division lines 17 to obtain the plural device chips 45. One of the plural device chips 45 thus obtained by the dividing step is shown in FIG. 7. As shown in FIG. 7, each device chip 45 includes the device 19 such as IC and LSI and the modified layer mark 43 as the chip identification information formed inside the substrate of the device chip 45 by laser marking.

In the case that each device chip 45 is formed from silicon (Si), the modified layer mark 43 cannot be visually recognized from the outside of the device chip 45. Accordingly, in reading the modified layer mark 43 as the chip identification information, an infrared camera must be used to image the modified layer mark 43. In the case that each device chip 45 is formed from a transparent material such as sapphire, the modified layer mark 43 can be visually recognized from the outside of the device chip 45.

The present invention is not limited to the details of the above described preferred embodiments. The scope of the invention is defined by the appended claims and all changes and modifications as fall within the equivalence of the scope of the claims are therefore to be embraced by the invention.

What is claimed is:

1. A device chip comprising:
a substrate; and
a device formed on the front side of said substrate,
wherein chip identification information is marked inside said substrate.

2. A manufacturing method for a device chip having chip identification information marked inside a substrate, said manufacturing method comprising:
a device wafer preparing step of preparing a device wafer including a base wafer, and a plurality of devices respectively formed in a plurality of regions partitioned by a plurality of crossing division lines on the front side of said base wafer;
a chip identification information marking step of applying a laser beam having a transmission wavelength to said device wafer prepared by said device wafer preparing step, to the device wafer from the back side of said device wafer in a condition where the focal point of said laser beam is set inside said base wafer at the positions respectively corresponding to said devices, thereby forming a plurality of modified layer marks as said chip identification information inside said base wafer at the positions respectively corresponding to said devices; and
a dividing step of dividing said device wafer along said division lines to obtain a plurality of device chips after performing said chip identification information marking step.
